(19) United States
(12) Patent Application Publication
(10) Pub. No.: US 2006/0236921 A1
(43) Pub. Date: Oct. 26, 2006

(54) Method of cleaning a substrate surface from a crystal nucleus

(75) Inventor: Christian Chovino, Dresden (DE)

Correspondence Address: GREGORY L. MAYBACK, P.A., 5722 S. FLAMINGO ROAD #232, FORT LAUDERDALE, FL, 33330, US

(73) Assignee: Advanced Mask Technology Center GmbH & Co. KG, Dresden (DE)

(21) Appl. No.: 11/400,870

(22) Filed: Apr. 10, 2006

(30) Foreign Application Priority Data
Apr. 8, 2005 (EP) 05007820.3

(51) Int. Cl. C30B 25/00; C30B 23/00; C30B 28/12; C30B 28/14

(52) U.S. Cl. 117/89

(57) ABSTRACT

A method of cleaning a substrate surface from a crystal nucleus in which the substrate surface is held in a condition under which a crystal growth is accelerated with respect to normal clean room and normal air conditions. In particular, light having a wavelength to induce a crystal growth is irradiated and, additionally, at least one reactive gas is fed at a higher concentration than under normal clean room and normal air conditions. After placing the substrate under these conditions, the grown crystals are removed, for example, by rinsing with water. As a consequence, the crystal nucleus is removed from the substrate surface.

### CROSS-REFERENCE TO RELATED APPLICATIONS

This application claims the priority under 35 U.S.C. § 119, of European Patent Application No. 05007820.3, filed Apr. 8, 2005; the entire disclosure of the prior application is herewith incorporated by reference in its entirety.

### BACKGROUND OF THE INVENTION

### Field of the Invention

The present invention relates to a method of cleaning a substrate surface from a crystal nucleus. In particular, the present invention refers to a method of cleaning a surface of a photomask that is commonly used for photolithographically patterning surfaces in the field of semiconductor technologies.

During the manufacture of a semiconductor device, components of the device usually are formed by patterning layers that are deposited on a silicon wafer. The patterning of these layers usually is accomplished by applying a resist material onto the layer that has to be patterned, and by subsequently exposing predetermined portions of the resist layer that is sensitive to the exposure wavelength. Thereafter, the regions that have been irradiated with the radiation are developed and the irradiated or radiated portions are removed subsequently. As a consequence, portions of the layer are masked by the generated photoresist pattern during a following process step, such as an etching step or an implantation step. After processing the exposed portions of the underlying layer, the resist mask is removed.

For patterning the resist layer, usually photolithographical masks or reticles are used for transferring a predetermined pattern onto the layer that is to be patterned. For example, a photomask, which can be used for optical lithography, includes a substrate made of a transparent material such as quartz glass, as well as a patterned layer that can be made of an opaque material, for example, a metal such as chromium. Alternatively, the patterned layer can be made of a phase-shifting semitransparent material such as molybdene silioxinitride (MoSiON). In other known photomasks, the quartz substrate itself is patterned to provide a phase-shifting mask. In addition, part of the quartz substrate can be covered with a pattern made of a phase shifting layer. The patterned material results in a modulation of the intensity of the transmitted light.

In present technologies, patterns are transferred or imaged from the mask to the wafer by UV-lithography, wherein an exposure wavelength of 193 nm is commonly used. Although such an exposure usually is conducted in a clean room atmosphere (in which most of the reactant gases are removed by special filters), reactions occur on the surface of the reticle, leading to an unwanted crystal growth. In particular, photoinduced reactions of contaminants, which are present on the photomask surface, with environmental impurities lead to a crystal growth and haze on the surface of the photomask or reticle. To be more specific, the contaminants present on the photomask act as crystal seeds or crystal nuclei from which crystals grow.

FIG. 4 shows an exemplary exposure tool in which a pattern is transferred from a reticle 10 to a wafer 13 by irradiating the reticle with light from an exposure or light source 18, which can, in particular, be an excimer laser emitting a wavelength of 193 nm. The light from the exposure source 18 is directed onto the reticle 10 through the deflecting element (mirror) 17 and the first lens system 16b acting as a collimator. The pattern on the reticle is imaged onto the wafer by the second lens system 16a acting as a projection objective. The reticle 10 is held by a stage 20. The two lens systems 16a, 16b and the reticle 10 are purged with purge air 19 which can for example be a mixture of air and nitrogen, the mixture being filtered by a primary filter 14 so as to remove amines or NHₓ groups from the purge air. In addition, a secondary filter 15 so as to remove the SOₓ groups from the purge air, and, optionally, additional filters such as a carbon filter or a filter for filtering other materials can be provided.

As is known, in particular Soₓ and NHₓ groups cause unwanted crystal growth. Although the concentrations of these contaminants are very low, for example less than 0.1 ppb for Soₓ and less than 0.55 ppb for NHₓ, crystal growth and haze are caused in these exposure tool environments. For example, ammonium sulfate (NH₄)₂SO₄ and ammonium nitrate NH₄NO₃ crystals grow on the reticle surface.

To get rid of the unwanted crystals and haze, after several exposure steps, the mask is cleaned in hot water, and, additionally, in liquids such as liquid ammonia to remove the top thin film that is susceptible to crystal growth. Thereby, the reticle surface is cleaned.

Such a method is disadvantageous because the optical properties of the reticle may be altered. In addition, crystal growth will, again, occur, especially due to the use of special chemicals, such as sulfuric acid, new crystal nuclei are introduced on the reticle surface. Accordingly, after some time, this method has to be repeated; thus it is time-consuming.

Generally, it is known to clean the reticle surfaces with a piranha clean (H₂SO₄/H₂O₂). In addition, it is known to clean the reticle surfaces with an NH₄OH or SC1(NH₄OH+H₂O₂) chemistry.

Another approach is based on the usage of UV-light that is adapted to decompose the reacting species on the reticle surface.

The reason for occurrence of the crystal growth is not entirely understood. In particular, it has been observed, that the crystal growth takes place in a certain clean room environment, whereas it does not take place in other clean room environments.

The publication “Improving photomask surface properties through a combination of dry and wet cleaning steps” by Florence Eschbach et al., Proceeding of SPIE, vol. 5446, 209-217 (2004), discloses experiments on photoinduced crystal growth on photomasks.

Because usage of thoroughly clean masks is a major task for exactly transferring the pattern from the mask to the wafer, there is a strong demand for obtaining a method of cleaning the surface of a photomask.

### SUMMARY OF THE INVENTION

It is accordingly an object of the invention to provide a method of cleaning a substrate surface from a crystal nucleus that overcomes the hereinafore-mentioned disadvantages of the heretofore-known devices and methods of this general type and that provides a method of cleaning a substrate surface from a crystal nucleus or a crystal seed.

With the foregoing and other objects in view, there is provided, in accordance with the invention, a method of cleaning a crystal nucleus off of a substrate surface, including the steps of setting accelerated growing conditions adapted to cause an accelerated crystal growth from a crystal nucleus, the accelerated growth being accelerated with respect to growth under normal or standard clean room and normal, standard, or ambient air conditions, the accelerated growing conditions including supplying energy to induce a crystal growth and feeding of at least one reactive gas at a higher concentration than under standard clean room and standard air conditions, exposing a substrate surface to the accelerated growing conditions to grow a crystal from the crystal nucleus, and removing the grown crystal.

With the objects of the invention in view, there is also provided a method of cleaning a crystal nucleus off of a substrate surface, including the steps of setting accelerated growing conditions to cause accelerated crystal growth from a crystal nucleus by supplying energy to induce the crystal growth and feeding at least one reactive gas to an environment for holding the substrate surface at a higher concentration than exists in a clean room and in ambient air conditions, the accelerated growth being accelerated with respect to growth under clean room and ambient air conditions, exposing a substrate surface to the accelerated growing conditions in the holding environment to grow a crystal from the crystal nucleus, and removing the grown crystal from the substrate surface.

In accordance with another mode of the invention, the method of cleaning the surface includes cleaning a photomask with the steps defined herein.

With the objects of the invention in view, there is also provided a method of cleaning a crystal nucleus off of a substrate surface, including the steps of setting accelerated growing conditions adapted to cause an accelerated crystal growth from a crystal nucleus, the accelerated growth being accelerated with respect to growth under standard clean room and air conditions, the accelerated growing conditions including supplying energy to induce a crystal growth and feeding of at least one reactive gas at a higher concentration than under standard clean room and standard air conditions, exposing a surface of a photomask to the accelerated growing conditions to grow a crystal from the crystal nucleus, and removing the grown crystal.

The present invention provides a method of cleaning a substrate surface from a crystal nucleus in which the substrate surface is held in a condition under which a crystal growth is accelerated with respect to normal clean room and normal air conditions.

As is well known, normal dry air includes 78.08% N₂, 20.95% O₂, 0.93% Ar, and, in addition, trace gases such as CO₂ (0.034%), H₂ (0.00005%), and others. In particular, the amount of reactive trace gases is very low. Usually, the air in clean rooms is stabilized with respect to temperature and humidity, and, in addition, is filtered to remove small particles. For example, the temperature in a clean room is 23±0.5° C. and the relative humidity thereof is 42%±3%. Except for the humidity, the composition of clean room air basically is identical with the composition of normal dry air.

According to the present invention, energy that induces a crystal growth is supplied to the substrate and, in addition, at least one reactive gas is fed to these substrates at a higher concentration of the specific gas than under normal clean room and normal air conditions to cause an accelerated crystal growth. The term “reactive gas” as used herein refers to a gas that will react with a crystal nucleus on a substrate surface. In particular, it includes any oxidizing or reducing gases, especially gaseous ammonia, oxygen, ozone, hydrogen, and water vapor. In particular, even if a certain reactive gas is not present in normal air or normal clean room air, it is clearly to be understood that the feature “at a higher concentration than under normal clean room and normal air conditions” means and includes any concentration of this reactive gas.

The energy that induces a crystal growth can be supplied by irradiating these substrate surfaces with electromagnetic radiation. Thereby, a photon induced crystal growth is promoted. Alternatively or additionally, the energy can be supplied by directly locally heating the substrate, thus causing a thermally induced crystal growth.

After placing the substrate under these conditions for sufficient time to enable a crystal growth, the grown crystals are removed. As a consequence, the crystal nucleus is removed from the substrate surface.

In accordance with a further mode of the invention, the step of supplying energy is carried out by irradiating with light.

In accordance with an added mode of the invention, the electromagnetic radiation that is irradiated on the substrate surface has a wavelength in the UV range, this wavelength being particularly suitable for inducing a crystal growth. In particular, the UV light is at a wavelength in a range between approximately 100 nm and approximately 400 nm.

Alternatively or additionally, the substrate surface can be irradiated, for example, with Infrared (1R) light, having a wavelength greater than 800 nm. Thereby, the substrate surface is heated. As a result, a thermally induced crystal growth takes place.

For cleaning a surface of a photomask, it is preferred to irradiate the photomask with light having a wavelength in a range of λₑₓ±20%, wherein λₑₓ denotes the exposure wavelength. In this case, when performing the cleaning method, similar reactions as during the exposure are caused.

In accordance with an additional mode of the invention, the accelerated growing conditions include feeding of at least one gas to the substrate surface, the at least one gas being adapted to react with the crystal nucleus.

In accordance with yet another mode of the invention, the conditions can be set by feeding gases that will react with the contaminants left on the substrate surface. Examples of such gases include ammonia, oxygen, ozone, hydrogen, and water vapor. In addition, preferably, a carrier gas such as N₂ or any other insert gas such as Ar or He is introduced. In particular, at the substrate surface, the concentration of at least one of the active gases, i.e., the gases that will react with the crystal nucleus, is higher than under normal clean room conditions.

In accordance with yet an additional mode of the invention, the at least one gas is fed at a predetermined flow rate. To be more specific, a flow rate of 0 to 0.5 l/min of the active gases is especially preferred. Accordingly, at the substrate surface, a concentration of the reactive gases of approximately 0.05% to 20% is especially preferred. In particular, for oxygen having a relatively high concentration in ambient air, a concentration of 21% to 40% is especially preferred.

In accordance with yet a further mode of the invention, it is advantageous to perform the method of the invention at a reduced pressure. In particular, a pressure of below 1 atm (1.013·10⁵ Pa) and, more specifically, from 10 to 10⁴ Pa, is preferred. By reducing the pressure, the atmosphere at the substrate surface can be controlled so that only the reactive gases for well-defined chemical reactions with the crystal seeds are present on the substrate surface.

Preferably, the chamber in which the cleaning process takes place is controlled at a pressure as specified above and, then, one or more reactive gases in combination with a carrier gas are fed, so that, at the substrate surface, a concentration of at least one reactive gas is higher than under normal clean room and normal air conditions.

After the crystals have been grown on these substrate surfaces, the crystals will be removed. In accordance with yet an added mode of the invention, it is especially preferred to remove the crystals by bringing them into contact with a liquid. In particular, by rinsing with the liquid, most of the crystals will be removed, the remaining crystals dissolving in the liquid. In addition, or alternatively, the crystals can be removed from the substrate surface by cleaning the substrate in a megasonic bath.

In accordance with again another mode of the invention, it is preferred to remove the grown crystal by bringing the substrate surface into contact with an ammonia-free and/or sulfate-free liquid. In this case, an additional contact with the contaminants, e.g., NHₓ and SOₓ groups, which substantially cause unwanted crystal growth, can be avoided.

In accordance with again another mode of the invention, the use of water, especially pure water, preferably, containing CO₂, is particularly desired because, thereby, no additional contaminant is introduced on the substrate surface.

In accordance with a concomitant mode of the invention, if after the step of exposing the substrate surface to the set conditions, the only liquid the substrate is brought into contact with is pure water, additional contaminants can be avoided. This is a major advantage with respect to conventional methods, according to which the substrate is cleaned with NH₄OH-based and/or H₂SO₄-based chemicals.

Other features that are considered as characteristic for the invention are set forth in the appended claims.

Although the invention is illustrated and described herein as embodied in a method of cleaning a substrate surface from a crystal nucleus, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 is a diagrammatic plan view of a photomask that can be cleaned with the method according to the invention;

FIG. 2 is a block circuit diagram of an exemplary device according to the invention for cleaning a crystal nucleus off of a substrate surface;

FIG. 3 is a diagrammatic illustration of a water bath for cleaning a crystal nucleus off of a substrate surface; and

FIG. 4 is a diagrammatic illustration of a prior art exposure chamber for exposing a resist material on a semiconductor substrate.

### DESCRIPTION OF THE PREFERRED EMBODIMENTS

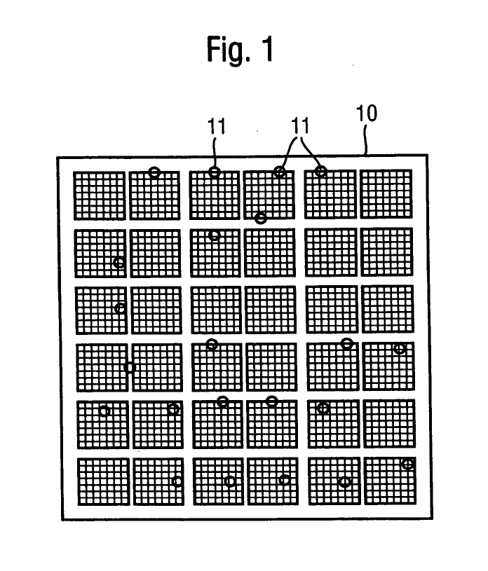

Referring now to the figures of the drawings in detail and first, particularly to FIG. 1 thereof, there is shown a photolithographic mask 10 that can be used for photolithographically transferring a predetermined pattern onto a photoresist material that is applied on a semiconductor substrate. As can be seen from FIG. 1, usually, the photomask includes a plurality of patterns that are transferred from the mask to the photoresist material by exposing the photoresist material with light that has been transmitted or reflected by the photomask. In addition, a plurality of crystal nuclei or crystal seeds 11 is left on the surface of the photomask.

As is apparent to a person skilled in the art of the present invention, the method of the present invention can equally be applied to any kind of photomask, including reflective or transmissive photomasks, UV, EUV, VIS, or other photomasks that are used in other wavelength regions.

As can be gathered from FIG. 1, the presence of haze or crystal growth on the surface of such a reticle will cause severe problems, since using one mask a plurality of wafers is exposed, and, consequently, a much greater plurality of chips is made. If the surface of the mask is contaminated, this large amount of chips will be defective.

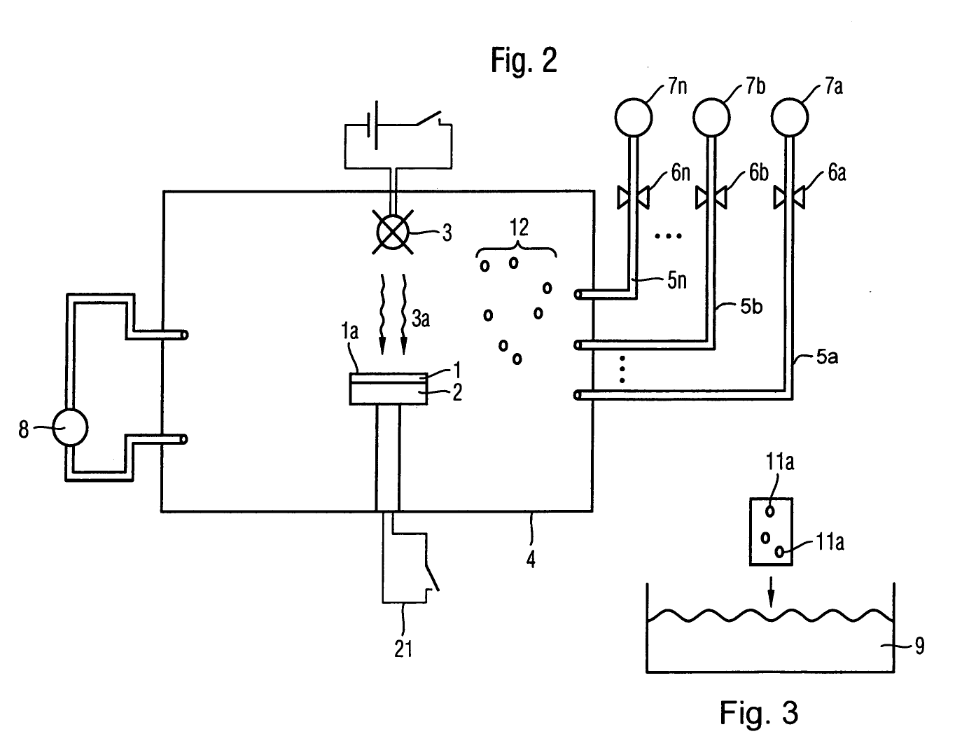

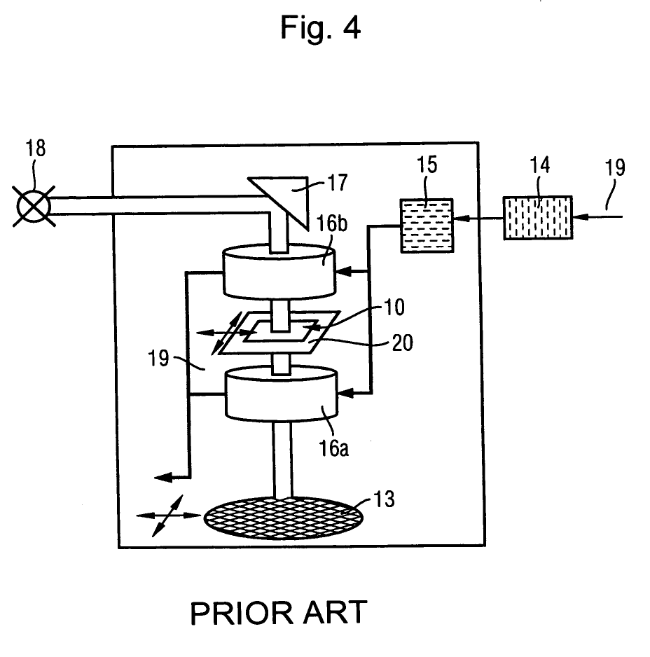

FIG. 2 illustrates a device for cleaning a substrate surface from a crystal nucleus. The substrate 1 is held by a substrate holder 2, the substrate surface 1a being exposed to the atmosphere. A heating device 21 for directly heating the substrate holder can be disposed at the substrate holder 2. The substrate holder 2 is enclosed by a chamber 4, in which a predetermined pressure can be set by a pump 8. A plurality of gas cylinders 7a, . . . , 7n is provided. The cylinders 7a, . . . , 7n are connected with the chamber 4 through gas lines 5a, . . . , 5n. The gas flow of a specific gas from the cylinder 7a, . . . , 7n to the chamber 4 can be controlled by the corresponding valve 6a, . . . , 6n. The light source 3 is provided to irradiate the substrate surface 1a with light of a specific wavelength. In particular, by irradiating the substrate 1 with the light 3a from the light source 3, a reaction of the crystal nucleus 11 with one or more of the gases 12 fed to the chamber 4 will be accelerated or even caused.

For performing the method of the present invention, a substrate 1 is placed on the substrate holder 2. The substrate can be, in particular, a reticle or a photomask. Other possible configurations for the substrate include a semiconductor wafer, a quartz substrate, or any other substrate that has one or more crystal nuclei 11 on it.

After optionally setting a predetermined pressure, by feeding appropriate gases to the chamber 4, a condition that is nearly similar to the condition of a clean room or an exposure tool, for example, is provided. In particular, an active gas such as oxygen (O₂), ammonia (NH₄), water vapor (H₂O), or hydrogen (H₂) is fed solely or in combination to the chamber 4. In particular, the active or reactive gas is fed so that a concentration thereof is higher than in normal air and normal clean room air.

By controlling the valves 6a to 6n, the flow rate of these active gases can be controlled. In particular, a flow rate of more than 0 to 0.5 l/min (0.5*10³ sccm, cubic centimeters per minute under standard conditions) of the active gases is set. More particularly, if three active gases are fed to the chamber 4, the sum of the individual flow rates equals a maximum of 0.5 l/min.

In addition, a carrier gas is fed to the chamber. As a carrier gas, N₂ or another inert gas such as Argon (Ar), Helium (He) or any other noble gas can be fed solely or in combination. Preferably, the total flow rate of the carrier gases is more than 0 to 10 l/min. In addition, the light source 3, here, a UV lamp 3, is caused to irradiate UV radiation. The UV lamp 3 can, for example, be a Xenon lamp, emitting a wavelength of 172 nm. In particular, the lamp preferably emits a radiation having a wavelength similar to the exposure wavelength of the specific reticle. For example, the wavelength of the UV lamp can be λex±20%, wherein λex denotes the exposure wavelength.

As an alternative, infrared radiation having an appropriate wavelength to heat the substrate can be irradiated onto the substrate surface. In such a case, the chamber 4 is held at room temperature of about 22° C. and at a varying pressure.

The conditions of examples of the invention are given in the following table.

| | | | | | Flow Rate |
|---|---|---|---|---|---|
| | | | | | of the |
| Example | | Reactive | | | Carrier |
| No. | Pressure | Gas | Flow Rate | | Gas |
| 1 | 1 atm | Ozone | 0.3 | l/min | 7 l/min |
| | (1.013 · 10⁵ Pa) | | | | |
| 2 | 40 Pa | Oxygen | 0.5 | l/min | 0.5 l/min |
| 3 | 1000 Pa | Oxygen | 0.5 | l/min | 0.5 l/min |
| 4 | 1 atm | Oxygen/ | 0.5/0.1 | l/min | 10 l/min |
| | (1.013 · 10⁵ Pa) | water | | | |
| | | vapor | | | |
| 5 | 10⁴ Pa | NH₃ | 0.2 | l/min | 8 l/min |
| 6 | 100 Pa | Hydrogen | 0.1 | l/min | 7 l/min |

The substrate 1 is held in the chamber 4 with the set conditions as described above for about 10 minutes to induce a crystal growth on the substrate surface. Thereafter, the substrate 1 is taken from the chamber 4 and rinsed with water, for example as shown in FIG. 3, by holding it into a water bath 9 so as to thoroughly clean the surface from the grown crystals 11a. After drying the substrate surface, the surface is entirely cleaned, with all the crystal nuclei removed from its surface.

Under the conditions as described above, the crystal growth will take place on the substrate surface 1a, thus consuming the residuals and the contaminants, which have originally been present on the surface of the photomask and which are usually responsible for the crystal growth in the wafer exposure tool. The crystal(s) 11a grown is/are easily rinsed off the surface. After this process, the mask becomes free of residuals and contaminants that are usually susceptible to crystal growth and haze.

I claim:

1. A method of cleaning a crystal nucleus off of a substrate surface, which comprises:
setting accelerated growing conditions adapted to cause an accelerated crystal growth from a crystal nucleus, the accelerated growth being accelerated with respect to growth under standard clean room and air conditions, the accelerated growing conditions comprising supplying energy to induce a crystal growth and feeding of at least one reactive gas at a higher concentration than under standard clean room and standard air conditions;
exposing a substrate surface to the accelerated growing conditions to grow a crystal from the crystal nucleus; and
removing the grown crystal.

2. The method according to claim 1, which further comprises carrying out the step of supplying energy by irradiating with light.

3. The method according to claim 2, which further comprises carrying out the light irradiating step by providing the light as UV light at a wavelength in a range between approximately 100 nm and approximately 400 nm.

4. The method according to claim 2, which further comprises carrying out the light irradiating step by providing the light as infrared light having a wavelength of more than 800 nm.

5. The method according to claim 1, wherein the accelerated growing conditions include feeding of at least one gas to the substrate surface, the at least one gas being adapted to react with the crystal nucleus.

6. The method according to claim 5, which further comprises carrying out the gas feeding step by selecting the at least one gas from the at least one of the group of gases consisting of ammonia, water vapor, hydrogen, and oxygen.

7. The method according to claim 5, which further comprising feeding the at least one gas at a predetermined flow rate.

8. The method according to claim 5, which further comprises additionally feeding an inert gas acting as a carrier gas to the substrate surface.

9. The method according to claim 1, which further comprises selecting the accelerated growing conditions to additionally include a pressure below 1.013*10⁵ Pa.

10. The method according to claim 1, which further comprises selecting the accelerated growing conditions to additionally include a pressure of between approximately 10 Pa and approximately 10⁴ Pa.

11. The method according to claim 1, which further comprises removing the grown crystal by contacting the substrate surface with a liquid.

12. The method according to claim 11, wherein the liquid is ammonia-free and sulfate-free water.

13. The method according to claim 1, which further comprises removing the grown crystal by contacting the substrate surface with at least one of an ammonia-free liquid and a sulfate-free liquid.

14. The method according to claim 12, wherein the liquid is water.

15. The method according to claim 1, wherein the substrate surface is a surface of a photomask.

16. A method of cleaning a crystal nucleus off of a substrate surface, which comprises:
setting accelerated growing conditions to cause accelerated crystal growth from a crystal nucleus by:
supplying energy to induce the crystal growth;
feeding at least one reactive gas to an environment for holding the substrate surface at a higher concentration than exists in a clean room and in ambient air conditions, the accelerated growth being accelerated with respect to growth under clean room and ambient air conditions;
exposing a substrate surface to the accelerated growing conditions in the holding environment to grow a crystal from the crystal nucleus; and
removing the grown crystal from the substrate surface.

17. The method according to claim 16, wherein the substrate surface is a surface of a photomask.

18. A method of cleaning a crystal nucleus off of a substrate surface, which comprises:
setting accelerated growing conditions adapted to cause an accelerated crystal growth from a crystal nucleus, the accelerated growth being accelerated with respect to growth under standard clean room and air conditions, the accelerated growing conditions comprising supplying energy to induce a crystal growth and feeding of at least one reactive gas at a higher concentration than under standard clean room and standard air conditions;
exposing a surface of a photomask to the accelerated growing conditions to grow a crystal from the crystal nucleus; and
removing the grown crystal.
